(19) United States
(12) Patent Application Publication
(10) Pub. No.: US 2021/0003640 A1
(43) Pub. Date: Jan. 7, 2021

(54) FAULT LOCATING METHOD AND SYSTEM BASED ON MULTI-LAYER EVALUATION MODEL

(71) Applicant: WUHAN UNIVERSITY, Hubei (CN)

(72) Inventors: Yigang HE, HUBEI (CN); Wenjie WU, HUBEI (CN); Hui ZHANG, HUBEI (CN); Liulu HE, HUBEI (CN)

(73) Assignee: WUHAN UNIVERSITY, Hubei (CN)

(21) Appl. No.: 16/689,110

(22) Filed: Nov. 20, 2019

(30) Foreign Application Priority Data
Jul. 1, 2019 (CN) 201910585829.5

(51) Int. Cl. G01R 31/62; G01R 31/12; G06N 3/04; G06N 3/08

(52) U.S. Cl. CPC G01R 31/62; G01R 31/1281; G01R 31/1272; G06N 3/084; G06N 3/0436

(57) ABSTRACT

The disclosure discloses a fault locating method based on a multi-layer evaluation model. Firstly, determine a fault type to be inspected and a fault symptom which able to accurately and effectively reflect a power transformer operation status and determine a weight of each fault type by using an association rule and a set pair analysis. Then, establish a DBN model to perform feature extraction and classification on multi-dimensional data of a fault. Finally, perform a comprehensive evaluation on an existing diagnosis result by using the D-S evidence theory. Accordingly, the supporting strength of the common target is reinforced, while the influence of divergent targets is reduced. As a result, the uncertainty in the diagnosis result is significantly reduced. The disclosure is mainly used to monitor and diagnose a status variable of the power transformer in a real-time manner, and treats power transformer status evaluation as a multi-property decision issue.

### CROSS-REFERENCE TO RELATED APPLICATION

This application claims the priority benefit of China application serial no. 201910585829.5, filed on Jul. 1, 2019. The entirety of the above-mentioned patent application is hereby incorporated by reference herein and made a part of this specification.

### BACKGROUND

### Technical Field

The disclosure relates to power transformer fault diagnosis, and particularly relates to a fault locating method and system based on a multi-layer evaluation model.

### Description of Related Art

Operating power apparatuses safely is the basis for safe and stable operation of a power grid. Particularly, as the key hub apparatus of a power system, the health level and the operation status of a large-scale power transformer are directly related to the safety and stability of the operation of the power grid. During operation, a power transformer is under the influences of high current density, high voltage, and external environmental factors, so the internal structure and circuits of the power transformer may possibly encounter a fault. Faults may be classified into sudden faults and latent faults based on the process of development, and may be classified into thermal faults, electrical faults, and mechanical faults based on the properties of faults. In addition, mechanical faults are generally present in the form of thermal faults or electrical faults. In summary, the possible reasons why a power transformer encounters a fault are mainly power discharge and overheating.

For a long time, the health level and operating status of power transformers are mainly determined through regular maintenance. The mode of regular maintenance which has scientific basis and is reasonable has effectively reduced sudden accidents of the apparatuses through years of practice and therefore ensured proper operation of the apparatuses to a certain degree. However, such a “clear cut” maintenance mode clearly has defects. That is, since the actual status of the power transformer is not taken into consideration, a phenomenon of blindly “over-treating minor issues” or “putting treatment on nothing” has been observed. As the scale of power grid has grown rapidly in recent years, the number of apparatuses in the power grid, has increased significantly, which causes heavier workloads. As a result, the issue of maintenance personnel shortage has become more and more severe. In particular, since the manufacturing quality of power grid apparatuses has been improved significantly, a large number of integrated apparatus which require few maintenances are adopted, and the apparatus maintenance and test periods set in the early times are no longer suitable for the advanced level of power apparatus diagnosis and management. Therefore, the work of status maintenance based on status evaluation technologies needs to be developed and implemented. Currently, how to improve the maintenance and repair level for the operation of power transformers, reduce the chance of fault occurrence, and implement a reasonable maintenance strategy to reduce relevant expenses are issues which the power industry needs to work on.

In various diagnostic algorithms commonly used nowadays, there is no sufficient associative analysis among respective status variables regarding the operation of power transformers, and the internal connections among various information is not enough, either. When a power transformer encounters a fault, the fault is usually not simply related to a single status variable. Therefore, a comprehensive analysis on variations of the respective status variables of the power transformer is required to determine the operation status and a potential fault. Both the traditional algorithms and smart technologies exhibit defects, and it is difficult to diagnose the fault of the power transformer simply by relying on one method. Therefore, it is worth exploring to combine two or more algorithms to complement each other to improve the accuracy of fault diagnosis. Researchers have attempted to combine a plurality of individual methods. However, the weights of a combinatory model may be too subjective or even include a negative weight if the weights are only based on expert experience. Therefore, how to more adequately process and describe multi-source monitoring data to effectively carry out a fusion analysis and resolve uncertainty resulting from single information is now an issue to work on.

### SUMMARY

The technical issue which the disclosure touches upon is to provide a fault locating method and system based on a multi-layer evaluation model in view of the insufficiency of the current individual diagnosis algorithms and the subjectivity of combinatory models resulting from weights determined based on expert experience. The evaluation on power transformer insulation status is treated as a multi-property decision issue, the diagnosis of a fault by the associated set pair analysis and deep belief network (DBN) algorithm is adopted as evidence for determination, and a two-layer fault locating model under two indices is established to monitor the status of a power transformer and identify a fault in a real-time manner.

A technical solution adopted by the disclosure for solving the technical issue thereof is to provide a fault locating method based on a multi-layer evaluation model. The fault locating method includes: (1) determining a power transformer fault type to be inspected according to historical data; (2) choosing a status variable which is the most representative and able to accurately and effectively reflect a power transformer operation status as a fault symptom representing each fault type of a power transformer; (3) determining a constant weight coefficient of each fault symptom under each of the fault type by using an association rule and a set pair analysis, determining a variable weight coefficient by using power transformer experimental data to be tested, and calculating a final weight corresponding to each of the fault type according to the constant weight coefficient and the variable weight coefficient that are determined, wherein the association rule is an associative coupling relationship between the fault type and the fault symptom determined in advance according to the historical data; (4) establishing a DBN model to perform feature extraction and classification on the fault symptom to obtain a classification result; and (5) synthesizing results of (3) and (4) by using a Dempster-Shafer (D-S) evidence theory as an evidence synthesis rule, calculating a confidence of each of the fault type, and choosing a highest fault type as a final determination result of an evidence inference decision.

Following the technical solution, (3) includes: (31) calculating a support and a confidence by using the historical data to obtain the associative coupling relationship between the fault type and the fault symptom and the weight coefficient; 32) collecting experimental data to respectively calculate a relative deterioration and a rating value of each fault type to determine the variable weight coefficient; 33) obtaining an identical-different-opposite evaluation matrix of the fault symptom by using relative deterioration data of the fault symptom, and obtaining a connection of each fault type and a connection of an overall operation status accordingly; and 34) determining the overall operation status of the power transformer, respectively substituting the identical-different-opposite evaluation matrix into a connection expression of each fault type for calculation if the fault is present, and performing normalization to obtain a corresponding weight.

Following the technical solution, (4) includes: 41) determining the number of input layer neurons according to a sample dimension number in (2), and performing unsupervised layer-by-layer training on the model by using a training set; 42) determining the number of output layer neurons according to the number of types of the power transformer fault type according to (1), and performing reverse fine-tuning by using a back propagation (BP) neural network; and 43) performing a test on the DBN model by using a test set, and outputting a result.

Following the technical solution, (5) includes: 51) respectively adopting results of (3) and (4) as a first independent evidence e1 and a second independent evidence e2 and respectively determining original basic probability distributions and uncertainty thereof according to a fuzzy evaluation model; 52) fusing evidence to determine the confidence Bₑₗ and a likelihood pₗ of each fault type, wherein the confidence Bₑₗ indicates a probability of being determined as the fault type, and the likelihood pₗ indicates a probability of possibly being the fault type, that is, a total of the confidence and the uncertainty; and 53) comparing the confidence of each fault type that is calculated, and the highest fault type is chosen as the final determination result of the evidence inference decision.

Following the technical solution, the fault type of the power transformer includes winding fault, iron core fault, current circuit overheating, humidified insulation, arc discharge, insulation aging, insulation oil deterioration, partial discharge, and oil flow discharge.

Following the technical solution, the fault symptom includes insulation oil dielectric loss, water content in oil, oil breakdown voltage, insulation resistance absorption ratio, polarization index, volume resistivity, H₂ content, iron core ground current, iron core insulation resistance, C₆H₆ content, C₄H₄ content, winding DC resistance mutual difference, CO relative gas production rate, CO₂ relative gas production rate, winding short circuit impedance initial value difference, winding insulation dielectric loss, winding capacitance initial value difference, C₂H₂ content, partial discharge quantity, gas content in oil, CH₄ content, neutral point oil flow electrostatic current, furfural content, and cardboard polymerization degree.

The disclosure also provides a fault locating system based on a multi-layer evaluation model. The fault locating system includes: a power transformer fault type and fault symptom determining module for determining a power transformer fault type to be inspected according to historical data, and choosing a status variable that is the most representative and able to accurately reflect a power transformer operation status as a fault symptom representing each of the fault type of a power transformer; a weight coefficient calculating module for determining a constant weight coefficient of each fault type by using an association rule and a set pair analysis, determining a variable weight coefficient by using power transformer experimental data to be tested, and calculating a final weight corresponding to each of the fault type according to the constant weight coefficient and the variable weight coefficient that are determined, wherein the association rule is an associative coupling relationship between the fault type and the fault symptom determined in advance according to the historical data; a DBN classifying module for establishing a DBN model to perform feature extraction and classification on the fault symptom of a fault to obtain a classification result; and a fault determining module for synthesizing results of the weight coefficient calculating module and the DBN classifying module by using a D-S evidence theory as an evidence synthesis rule, calculating a confidence of each of the fault type, and choosing a highest fault type as a final determination result of an evidence inference decision.

Following the technical solution, the weight coefficient calculating module includes: a constant weight coefficient calculating module for calculating a support and a confidence by using the historical data to obtain an association coupling relationship between the fault type and the fault symptom and the constant weight coefficient; a variable weight coefficient calculating module for collecting experimental data and respectively calculating a relative deterioration and a rating value of each of the fault type and determining the variable weight coefficient; a connection calculating module for obtaining an identical-different-opposite evaluation matrix of the fault symptom by using relative deterioration data of the fault symptom, and obtaining a connection of each of the fault type and a connection of an overall operation status accordingly; a normalizing module for determining the overall operation status of the power transformer, and respectively substituting the identical-different-opposite evaluation matrix into a connection expression of each of the fault type for calculation if the fault is present, and performing normalization to obtain a corresponding weight.

Following the technical solution, the DBN classifying module includes: a layer-by-layer training module for determining the number of input layer neurons according to a sample dimension number of the power transformer fault type, and performing unsupervised layer-by-layer training on a model by using a training set; a reverse fine-tuning module for determining the number of output layer neurons according to the number of types of the power transformer fault type, performing reverse fine-tuning by using a BP neural network; a test module for performing a test on the DBN model by using a test set, and outputting a result.

Following the technical solution, the fault determining module includes: an original basic probability distribution and uncertainty module for respectively adopting results of the weight coefficient calculating module and the DBN classifying module as a first independent evidence e1 and a second independent evidence e2 and respectively determining original basic probability distributions and uncertainty thereof according to a fuzzy evaluation model; an evidence fusing module for fusing evidence to determine a confidence Bₑₗ and a likelihood pₗ of each of the fault type, wherein the confidence Bₑₗ indicates a probability of being determined as the fault type, and the likelihood pₗ indicates a probability of possibly being the fault type, that is, a total of the confidence and the uncertainty; and a result determining module for comparing the confidence of each of the fault type that is calculated and choosing the highest fault type as the final determination result of the evidence inference decision.

The beneficial effects brought by the disclosure are as follows. By combining the set pair analysis theory and the association rule, the influence of the subjective opinion of the expert system on the accuracy of weights can be properly reduced. Adopting the deep belief network for deep learning creates a significant advantage in handling feature extraction of high dimensional, non-linear data. In the disclosure, the evaluation on power transformer insulation status is treated as a multi-property decision issue. A two-layer fault locating model under two indices is established. The D-S evidence theory has a focusing effect capable of reinforcing the supporting strength of the common target, while reducing the influence of divergent targets. The disclosure is capable of monitoring the power transformer operation status and identifying a fault occurrence in a real-time manner.

### BRIEF DESCRIPTION OF THE DRAWINGS

The accompanying drawings are included to provide a further understanding of the disclosure, and are incorporated in and constitute a part of this specification. The drawings illustrate embodiments of the disclosure and, together with the description, serve to explain the principles of the disclosure.

FIG. 1 is a flowchart illustrating a fault locating method based on a multi-layer evaluation model according to the disclosure.

FIG. 2 is a schematic diagram illustrating a membership function with correspondence between power transformer operation status level and relative deterioration.

FIG. 3 is a block diagram illustrating a fault locating system based on a multi-layer evaluation model according to the disclosure.

### DESCRIPTION OF THE EMBODIMENTS

Reference will now be made in detail to the present preferred embodiments of the disclosure, examples of which are illustrated in the accompanying drawings. Wherever possible, the same reference numbers are used in the drawings and the description to refer to the same or like parts.

In order to more clearly describe the objective, technical solution, and advantages of the disclosure, the disclosure will be described in detail in the following with reference to the accompanying drawings and embodiments. It should be understood that the detailed embodiments described herein merely serve to describe the disclosure but shall not be construed as limitations on the disclosure.

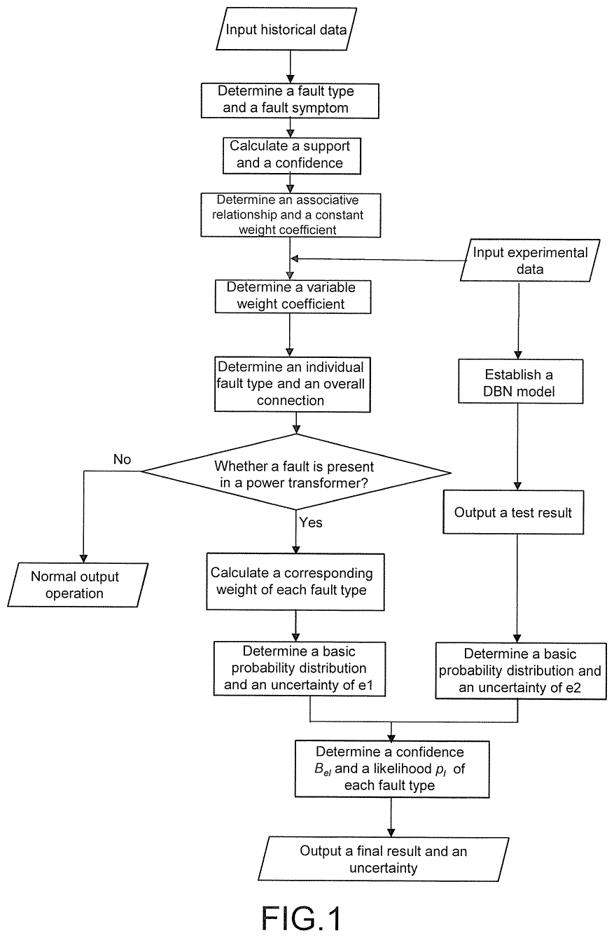

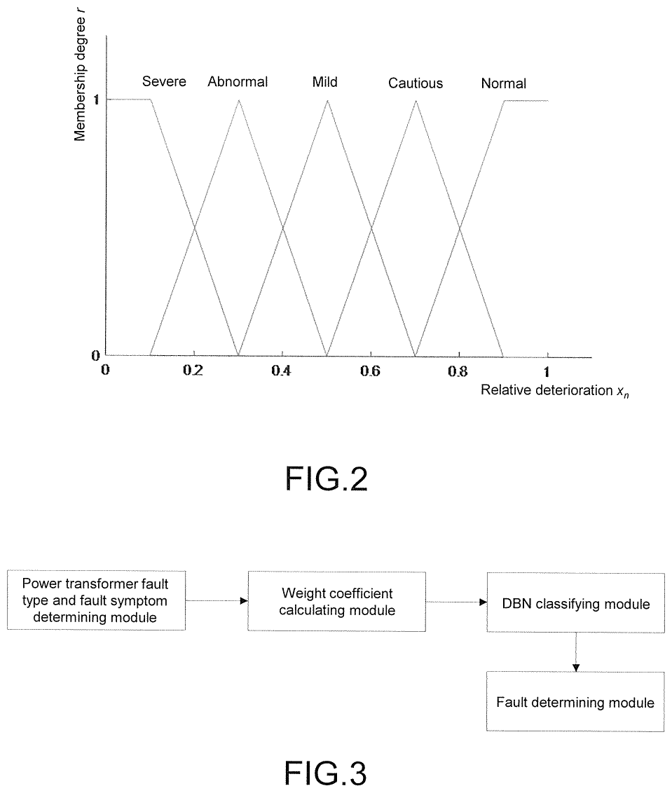

Referring to FIG. 1, FIG. 1 is a flowchart illustrating a fault locating method based on a multi-layer evaluation model according to the disclosure. The fault locating method includes the following.

(1) A fault type to be inspected is determined.

There are many types of power transformer faults, and it is difficult to classify the types of power transformer faults by a certain classification method. In the embodiment, the common power transformer faults are classified into 9 fault types mainly based on “Guidelines for Evaluating Status of Oil-immersed Power Transformers (Inductors)” as well as actual operating experiences and fault classification sets that are more successful in previous experiences. The fault types are as shown in Table 1.

TABLE 1
Fault Type of Power Transformer

| Item set | Fault Type |
|---|---|
| F₁ | Winding fault |
| F₂ | Iron core fault |
| F₃ | Current circuit overheating |
| F₄ | Humidified insulation |
| F₅ | Arc discharge |
| F₆ | Insulation aging |
| F₇ | Insulation oil deterioration |
| F₈ | Partial discharge |
| F₉ | Oil flow discharge |

(2) A status variable which is the most representative and able to accurately and effectively reflect the operation status of the power transformer is chosen as the fault symptom representing each fault type of the power transformer. The fault symptom should be chosen from status variables with complete parameters. In general, the fault symptom may be chosen from the 24 status variables in Table 2 for status evaluation.

TABLE 2
Fault Symptom of Power Transformer

| Item set | Fault symptom |
|---|---|
| S₁ | Insulation oil dielectric loss |
| S₂ | Water content in oil |
| S₃ | Oil breakdown voltage |
| S₄ | Insulation resistance absorption ratio |
| S₅ | Polarization index |
| S₆ | Volume resistivity |
| S₇ | H₂ content |
| S₈ | Iron core ground current |
| S₉ | Iron core insulation resistance |
| S₁₀ | C₂H₆ content |
| S₁₁ | C₂H₄ content |
| S₁₂ | Winding DC resistance mutual difference |
| S₁₃ | CO relative gas production rate |
| S₁₄ | CO₂ relative gas production rate |
| S₁₅ | Winding short circuit impedance initial value difference |
| S₁₆ | Winding insulation dielectric loss |
| S₁₇ | Winding capacitance initial value difference |
| S₁₈ | C₂H₂ content |
| S₁₉ | Partial discharge quantity |
| S₂₀ | Gas content in oil |
| S₂₁ | CH₄ content |
| S₂₂ | Neutral point oil flow electrostatic current |
| S₂₃ | Furfural content |
| S₂₄ | Cardboard polymerization degree |

(3) The weight of each fault type is determined by using an association rule and a set pair analysis. Specifically, the details are as follows.

(31) A support and a confidence are calculated by using historical data to obtain an associative coupling relationship between the fault type and the fault symptom and a weight coefficient.

During the actual operation process, a fault occurrence of the power transformer is usually related to multiple fault symptoms, and one fault symptom may also correspond to multiple fault types. Therefore, the associative coupling relationship between the fault type and the fault symptom, i.e., the association rule, needs to be determined in advance according to the historical data. In addition, by calculating the support, the probability of the association rule may be represented. That is, the association degree is higher if the support is higher. By calculating the confidence, the confidence level of the association rule may be represented. That is, the confidence level is higher if the confidence is higher.

It is set that a transaction database is D, and the number of all the transactions in D is: |D|. Given that A and B respectively represent the assumption and the conclusion of the association rule, the support of the association rule A⇒B is the proportion of the case where A∪B is included in D, which is represented as:

$$support ( A ⇒ B ) = P ( A ⋃ B ) = \frac{f ( A ⋃ B )}{\vert D \vert} \times 100 \% .$$

In general, the minimum support threshold is set at 70%. In other words, an association rule with a value higher than the minimum support threshold is meaningful.

The confidence of the association rule A⇒B is the proportion of the case where A as well as A∪B is included in D.

$$confidence ( A ⇒ B ) = {C}_{A , B} = P ( B \vert A ) = \frac{f ( A ⋃ B )}{f ( A )} \times 1 \; 00 \%$$

The expression of a constant weight coefficient for each fault symptom under the fault type is represented as:

$${w}_{m , n} = \frac{{c}_{m n}}{{Σ}_{k = 1}^{{N}_{m}} {c}_{m , k}}$$

wherein w_{m,n} is a constant weight of a fault symptom Sb in a fault type Fm, C_{m,n} is a corresponding confidence, and Nₘ is the number of fault symptoms in the fault type Fm.

32) Experimental data is collected to respectively calculate a relative deterioration xₙ and a rating value yₘ of each fault type to determine a variable weight coefficient w′ₘ,

$${x}_{n} = \frac{{z}^{′} - {z}_{n}}{{z}^{′} - {z}_{f}}$$

$${y}_{m} = {Σ}_{n = 1}^{M} {x}_{n} {w}_{m , n}$$

$${w}_{m}^{′} = ( \frac{1}{{N}_{m}} {y}_{m}^{- 1} ) / ( {Σ}_{s = 1}^{M} {w}_{S} {y}_{S}^{- 1} )$$

wherein zₙ, is a current trial value with an estimate, z′ is a warning value of the fault symptom, and z_{f} is an initial value of the fault symptom.

33) By using relative deterioration data of the fault symptom, an identical-different-opposite evaluation matrix of the fault symptom is obtained, and a connection of each fault type and a connection of the overall operation status are obtained accordingly.

TABLE 3
Relationship among operation status level,
relative deterioration, and connection

| Oper- | | | | | |
|---|---|---|---|---|---|
| ation | | | | | |
| status | Normal | Cautious | Mild | Abnormal | Severe |
| Deteri- | 0.8 to 1 | 0.6 to 0.8 | 0.4 to 0.6 | 0.2 to 0.4 | 0 to 0.2 |
| oration | | | | | |
| Connec- | 0.6 to 1 | 0.2 to 0.6 | −0.2 to 0.2 | −0.6 to −0.2 | −1.0 to −0.6 |
| tion | | | | | |

An equalization method is adopted for a difference degree coefficient matrix of multivariate connection, and the connection μₘ of each of the fault type and the connection μ′ of the overall operation status are obtained accordingly.

μₘ=WₘRₘE

μ′=W′R′E

E=[1 0.5 0 −0.5 −1]^{T}

wherein Wₘ and Rₘ are respectively a constant weight coefficient matrix and an identical-different-opposite evaluation matrix of a fault symptom set corresponding to the fault type, E is an identical-different-opposite coefficient matrix, W′ and R′ are respectively a variable weight coefficient matrix and an identical-different-opposite evaluation matrix of a fault type set.

34) Through a comparison with reference to Table 3, the overall operation status of the power transformer is determined. If a fault is present, the identical-different-opposite evaluation matrix is respectively substituted into a connection expression of each fault type for calculation, and normalization is performed to obtain a corresponding weight.

$${Q}_{m =} \frac{{e}^{- {μ}_{m}}}{{Σ}_{k = 1}^{{N}_{m}} {e}^{- {μ}_{m}}}$$

(1) A deep belief network (DBN) model is established to perform feature extraction and classification on multi-dimensional data of the fault.

The DBN model is one of the deep learning models, and is an effective method for building a multi-layer neural network from unsupervised data. The DBN model is advantageous in handling feature extraction of high dimensional and non-linear data, and is able to provide better classification results thus improving the classification accuracy. The DBN model is mainly formed by a plurality of restricted Boltzmann machines (RBM), and model training is carried out through layer-by-layer unsupervised learning. Accordingly, the issue that the conventional neural network methods are not compatible with multi-layer network training is resolved. Besides, the algorithm of DBN combines data feature extraction and classification, and exhibits universality to a certain level, so issues such as curse of dimensionality and insufficient diagnosis capability can be effectively prevented from arising. The processes of establishing a DBN model are as follows.

41) The number of input layer neurons is determined according to the number of fault symptoms in (2), and unsupervised layer-by-layer training is performed on the model by using a training set. 42) The number of output layer neurons is determined according to the number of fault types according to (1), and reverse fine-tuning is performed by using a BP neural network. 43) A test on the model is performed by using a test set, and results are output.

(5) The results of (3) and (4) are synthesized by using the D-S evidence theory, and eventually a comprehensive evaluation determination result is generated.

The evidence synthesis rule is the core of the D-S evidence theory, and is a strict “AND” algorithm which satisfies the commutative law and the associative law. The basic probability distribution of the common focal element of a plurality of belief functions is positively proportional to the respective basic probability distributions thereof. Therefore, the D-S evidence theory has a focusing effect and is capable of reinforcing the supporting strength of the common target and reducing the influence of divergent targets. Regarding the evaluation on the insulation status of the power transformer, all the factor indices of the factor layer may be synthesized as independent evidence sources, and eventually a comprehensive evaluation on the common target, i.e., the insulation status of the power transformer, is generated. The details are as follows.

51) By respectively adopting the results of (3) and (4) as independent evidences e1 and e2, the original basic probability distributions and uncertainty thereof are respectively determined according to a fuzzy evaluation model,

$$m ( {F}_{a} ) = \frac{{y}_{i}}{1 + \frac{1}{2} {Σ ( {t}_{j} - {y}_{j} )}^{2}}$$

wherein tⱼ, yⱼ are respectively an expected output value and an actual output value, and Fₐ is a fault type.

The uncertainty: m(x)=1−Σm(Fₐ)

52) Evidence is fused to determine the confidence Bₑₗ and likelihood pₗ of each of the fault type, wherein the confidence indicates the probability of being determined as the fault type, and the likelihood indicates the probability of possibly being the fault type, i.e., the total of the confidence and the uncertainty,

$${B}_{e l} = {e}_{1} ⊕ {e}_{2} ( {F}_{a} ) = \frac{{m}_{1} ( {F}_{a} ) \cdot {m}_{2} ( {F}_{a} ) + {m}_{1} ( {F}_{a} ) \cdot {m}_{2} ( x ) + {m}_{2} ( {F}_{a} ) \cdot {m}_{1} ( x )}{K}$$

$${e}_{1} ⊕ {e}_{2} ( x ) = \frac{{m}_{1} ( x ) \cdot {m}_{2} ( x )}{K}$$

$${p}_{l} = {B}_{e l} + {e}_{1} ⊕ {e}_{2} ( x )$$

wherein m₁(Fₐ) and m₂(Fₐ) respectively indicate the basic probabilities that the evidences e1 and e2 are determined as the fault type Fₐ, m₁(x) and m₂(x) respectively indicate the uncertainty that the evidences e1 and e2 are uncertain to be determined as the fault type, and K is a conflict factor.

$$K = 1 - {Σ}_{{F}_{i} ⋂ {F}_{j} = ∅} {Π}_{{1 \leq i \leq N }_{1 \leq j \leq N}} {m}_{1} ( {F}_{i} ) \cdot {m}_{2} ( {F}_{j} )$$

53) The confidence of each fault type calculated is compared, and the highest fault type is chosen as the final determination result of the evidence inference decision.

In the disclosure, the fault symptom which is the most representative and able to accurately and effectively reflect the power transformer operation status is chosen. The set pair theory and the association rule are combined, and the connection between the fault symptom and the fault type is investigated in depth. By using the support and the confidence as evaluation metrics, the influence of the subjective opinions of the expert system on the accuracy of weights can be reduced. In addition, by implementing the deep belief network advantageous in handling feature extraction of high dimensional, non-linear data and establishing a two-layer fault locating model using two algorithms as basis, the supporting strength of the common target is reinforced, while the influence of divergent targets is reduced. Accordingly, the uncertainty in the diagnosis result is significantly reduced. Applications and experimental results indicate that the method of the disclosure improves by 3.67% as compared to one not using the deep belief network. Accordingly, the method of the disclosure is proven effective.

To implement the method according to the embodiment of the disclosure, the disclosure further provides a fault locating system based on a multi-layer evaluation model. As shown in FIG. 3, the fault locating system includes: a power transformer fault type and fault symptom determining module for determining a power transformer fault type to be inspected according to historical data, and choosing a status variable that is the most representative and able to accurately reflect a power transformer operation status as a fault symptom representing each of the fault type of a power transformer; a weight coefficient calculating module for determining a constant weight coefficient of each of the fault type by using an association rule and a set pair analysis, determining a variable weight coefficient by using power transformer experimental data to be tested, and calculating a final weight corresponding to each of the fault type according to the constant weight coefficient and the variable weight coefficient that are determined, wherein the association rule is an associative coupling relationship between the fault type and the fault symptom determined in advance according to the historical data; a DBN classifying module for establishing a DBN model to perform feature extraction and classification on the fault symptom of a fault to obtain a classification result; and a fault determining module for synthesizing results of Steps (3) and (4) by using a D-S evidence theory as an evidence synthesis rule, calculating a confidence of each of the fault type, and choosing a highest fault type as the final determination result of an evidence inference decision.

More specifically, the weight coefficient calculating module includes: a constant weight coefficient calculating module for calculating a support and a confidence by using the historical data to obtain an associative coupling relationship between the fault type and the fault symptom and the constant weight coefficient; a variable weight coefficient calculating module for collecting experimental data and respectively calculating a relative deterioration and a rating value of each of the fault type to determine the variable weight coefficient ; a connection calculating module for obtaining an identical-different-opposite evaluation matrix of the fault symptom by using relative deterioration data of the fault symptom, and obtaining a connection of each of the fault type and a connection of an overall operation status accordingly; a normalizing module for determining the overall operation status of the power transformer, and respectively substituting the identical-different-opposite evaluation matrix into a connection expression of each of the fault type for calculation if the fault is present, and performing normalization to obtain a corresponding weight.

More specifically, the DBN classifying module includes: a layer-by-layer training module for determining the number of input layer neurons according to a sample dimension number of the power transformer fault type, and performing unsupervised layer-by-layer training on a model by using a training set; a reverse fine-tuning module for determining the number of output layer neurons according to the number of types of the power transformer fault type, performing reverse fine-tuning by using a BP neural network; and a test module for performing a test on the DBN model by using a test set, and outputting a result.

More specifically, the fault determining module includes: an original basic probability distribution and uncertainty module for respectively adopting results of the weight coefficient calculating module and the DBN classifying module as a first independent evidence e1 and a second independent evidence e2 and respectively determining original basic probability distributions and uncertainty thereof according to a fuzzy evaluation model; an evidence fusing module for fusing evidence to determine a confidence Bₑₗ and a likelihood pₗ of each of the fault type, wherein the confidence Bₑₗ indicates a probability of being determined as the fault type, and the likelihood pₗ indicates a probability of possibly being the fault type, that is, a total of the confidence and the uncertainty; and a result determining module for comparing the confidence of each fault type that is calculated and choosing the highest fault type as the final determination result of the evidence inference decision.

It will be apparent to those skilled in the art that various modifications and variations can be made to the structure of the disclosure without departing from the scope or spirit of the disclosure. In view of the foregoing, it is intended that the disclosure cover modifications and variations of this disclosure provided they fall within the scope of the following claims and their equivalents.

What is claimed is:

1. A fault locating method based on a multi-layer evaluation model, comprising:
(1) determining a power transformer fault type to be inspected according to historical data;
(2) choosing a status variable which is the most representative and able to accurately and effectively reflect a power transformer operation status as a fault symptom representing each fault type of a power transformer;
(3) determining a constant weight coefficient of each fault symptom under each of the fault type by using an association rule and a set pair analysis, determining a variable weight coefficient by using power transformer experimental data to be tested, and calculating a final weight corresponding to each of the fault type according to the constant weight coefficient and the variable weight coefficient that are determined, wherein the association rule is an associative coupling relationship between the fault type and the fault symptom determined in advance according to the historical data;
(4) establishing a deep belief network (DBN) model to perform feature extraction and classification on the fault symptom to obtain a classification result; and
(5) synthesizing results of (3) and (4) by using a Dempster-Shafer (D-S) evidence theory as an evidence synthesis rule, calculating a confidence of each of the fault type, and choosing a highest fault type as a final determination result of an evidence inference decision.

2. The fault locating method based on the multi-layer evaluation model as claimed in claim 1, wherein (3) comprises:
31) calculating a support and a confidence by using the historical data to obtain the associative coupling relationship between the fault type and the fault symptom and the weight coefficient;
32) collecting experimental data to respectively calculate a relative deterioration and a rating value of each of the fault type to determine the variable weight coefficient;
33) obtaining an identical-different-opposite evaluation matrix of the fault symptom by using relative deterioration data of the fault symptom, and obtaining a connection of each of the fault type and a connection of an overall operation status accordingly; and
34) determining the overall operation status of the power transformer, respectively substituting the identical-different-opposite evaluation matrix into a connection expression of each of the fault type for calculation if the fault is present, and performing normalization to obtain a corresponding weight.

3. The fault locating method based on the multi-layer evaluation model as claimed in claim 1, wherein (4) comprises:
41) determining the number of input layer neurons according to a sample dimension number in (2), and performing unsupervised layer-by-layer training on the model by using a training set;
42) determining the number of output layer neurons according to the number of types of the power transformer fault type according to (1), and performing reverse fine-tuning by using a back propagation (BP) neural network; and
43) performing a test on the DBN model by using a test set, and outputting a result.

4. The fault locating method based on the multi-layer evaluation model as claimed in claim 1, wherein (5) comprises:
51) respectively adopting results of (3) and (4) as a first independent evidence el and a second independent evidence e2 and respectively determining original basic probability distributions and uncertainty thereof according to a fuzzy evaluation model;
52) fusing evidence to determine the confidence Bₑₗ and a likelihood pₗ of each of the fault type, wherein the confidence Bₑₗ indicates a probability of being determined as the fault type, and the likelihood pₗ indicates a probability of possibly being the fault type, that is, a total of the confidence and the uncertainty; and
53) comparing the confidence of each of the fault type that is calculated, and the highest fault type is chosen as the final determination result of the evidence inference decision.

5. The fault locating method based on the multi-layer evaluation model as claimed in claim 4, wherein the fault type of the power transformer comprises winding fault, iron core fault, current circuit overheating, humidified insulation, arc discharge, insulation aging, insulation oil deterioration, partial discharge, and oil flow discharge.

6. The fault locating method based on the multi-layer evaluation model as claimed in claim 4, wherein the fault symptom comprises insulation oil dielectric loss, water content in oil, oil breakdown voltage, insulation resistance absorption ratio, polarization index, volume resistivity, H₂ content, iron core ground current, iron core insulation resistance, C₂H₆ content, C₂H₄ content, winding DC resistance mutual difference, CO relative gas production rate, CO₂ relative gas production rate, winding short circuit impedance initial value difference, winding insulation dielectric loss, winding capacitance initial value difference, C₂H₂ content, partial discharge quantity, gas content in oil, CH₄ content, neutral point oil flow electrostatic current, furfural content, and cardboard polymerization degree.

7. A fault locating system based on a multi-layer evaluation model, comprising:
a power transformer fault type and fault symptom determining module for determining a power transformer fault type to be inspected according to historical data, and choosing a status variable that is the most representative and able to accurately reflect a power transformer operation status as a fault symptom representing each fault type of a power transformer;
a weight coefficient calculating module for determining a constant weight coefficient of each of the fault type by using an association rule and a set pair analysis, determining a variable weight coefficient by using power transformer experimental data to be tested, and calculating a final weight corresponding to each of the fault type according to the constant weight coefficient and the variable weight coefficient that are determined, wherein the association rule is an associative coupling relationship between the fault type and the fault symptom determined in advance according to the historical data;
a deep belief network (DBN) classifying module for establishing a DBN model to perform feature extraction and classification on the fault symptom of a fault to obtain a classification result; and
a fault determining module for synthesizing results of the weight coefficient calculating module and the DBN classifying module by using a Dempster-Shafer (D-S) evidence theory as an evidence synthesis rule, calculating a confidence of each of the fault type, and choosing a highest fault type as a final determination result of an evidence inference decision.

8. The fault locating system based on the multi-layer evaluation model as claimed in claim 7, wherein the weight coefficient calculating module comprises:
a constant weight coefficient calculating module for calculating a support and a confidence by using the historical data to obtain an associative coupling relationship between the fault type and the fault symptom and the constant weight coefficient;
a variable weight coefficient calculating module for collecting experimental data and respectively calculating a relative deterioration and a rating value of each of the fault type to determine the variable weight coefficient ;
a connection calculating module for obtaining an identical-different-opposite evaluation matrix of the fault symptom by using relative deterioration data of the fault symptom, and obtaining a connection of each of the fault type and a connection of an overall operation status accordingly;
a normalizing module for determining the overall operation status of the power transformer, and respectively substituting the identical-different-opposite evaluation matrix into a connection expression of each of the fault type for calculation if the fault is present, and performing normalization to obtain a corresponding weight.

9. The fault locating system based on the multi-layer evaluation model as claimed in claim 7, wherein the DBN classifying module comprises:
a layer-by-layer training module for determining the number of input layer neurons according to a sample dimension number of the power transformer fault type, and performing unsupervised layer-by-layer training on a model by using a training set;
a reverse fine-tuning module for determining the number of output layer neurons according to the number of types of the power transformer fault type and performing reverse fine-tuning by using a back propagation (BP) neural network;
a test module for performing a test on the DBN model by using a test set, and outputting a result.

10. The fault locating system based on the multi-layer evaluation model as claimed in claim 7, wherein the fault determining module comprises:
an original basic probability distribution and uncertainty module for respectively adopting results of the weight coefficient calculating module and the DBN classifying module as a first independent evidence e1 and a second independent evidence e2 and respectively determining original basic probability distributions and uncertainty thereof according to a fuzzy evaluation model;
an evidence fusing module for fusing evidence to determine a confidence Bₑₗ and a likelihood pₗ of each of the fault type, wherein the confidence Bₑₗ indicates a probability of being determined as the fault type, and the likelihood pₗ indicates a probability of possibly being the fault type, that is, a total of the confidence and the uncertainty; and
a result determining module for comparing the confidence of each of the fault type calculated and choosing the highest fault type as the final determination result of the evidence inference decision.

11. The fault locating method based on the multi-layer evaluation model as claimed in claim 2, wherein (5) comprises:
51) respectively adopting results of (3) and (4) as a first independent evidence el and a second independent evidence e2 and respectively determining original basic probability distributions and uncertainty thereof according to a fuzzy evaluation model;
52) fusing evidence to determine the confidence Bₑᵢ and a likelihood pᵢ of each of the fault type, wherein the confidence Bₑᵢ indicates a probability of being determined as the fault type, and the likelihood pᵢ indicates a probability of possibly being the fault type, that is, a total of the confidence and the uncertainty; and
53) comparing the confidence of each of the fault type that is calculated, and the highest fault type is chosen as the final determination result of the evidence inference decision.

12. The fault locating method based on the multi-layer evaluation model as claimed in claim 11, wherein the fault type of the power transformer comprises winding fault, iron core fault, current circuit overheating, humidified insulation, arc discharge, insulation aging, insulation oil deterioration, partial discharge, and oil flow discharge.

13. The fault locating method based on the multi-layer evaluation model as claimed in claim 11, wherein the fault symptom comprises insulation oil dielectric loss, water content in oil, oil breakdown voltage, insulation resistance absorption ratio, polarization index, volume resistivity, H₂ content, iron core ground current, iron core insulation resistance, C₂H₆ content, C₂H₄ content, winding DC resistance mutual difference, CO relative gas production rate, CO₂ relative gas production rate, winding short circuit impedance initial value difference, winding insulation dielectric loss, winding capacitance initial value difference, C₂H₂ content, partial discharge quantity, gas content in oil, CH₄ content, neutral point oil flow electrostatic current, furfural content, and cardboard polymerization degree.

14. The fault locating method based on the multi-layer evaluation model as claimed in claim 3, wherein (5) comprises:
51) respectively adopting results of (3) and (4) as a first independent evidence e1 and a second independent evidence e2 and respectively determining original basic probability distributions and uncertainty thereof according to a fuzzy evaluation model;
52) fusing evidence to determine the confidence Bₑₗ and a likelihood pₗ of each of the fault type, wherein the confidence Bₑₗ indicates a probability of being determined as the fault type, and the likelihood pₗ indicates a probability of possibly being the fault type, that is, a total of the confidence and the uncertainty; and
53) comparing the confidence of each of the fault type that is calculated, and the highest fault type is chosen as the final determination result of the evidence inference decision.

15. The fault locating method based on the multi-layer evaluation model as claimed in claim 14, wherein the fault type of the power transformer comprises winding fault, iron core fault, current circuit overheating, humidified insulation, arc discharge, insulation aging, insulation oil deterioration, partial discharge, and oil flow discharge.

16. The fault locating method based on the multi-layer evaluation model as claimed in claim 14, wherein the fault symptom comprises insulation oil dielectric loss, water content in oil, oil breakdown voltage, insulation resistance absorption ratio, polarization index, volume resistivity, H₂ content, iron core ground current, iron core insulation resistance, C₂H₆ content, C₂H₄ content, winding DC resistance mutual difference, CO relative gas production rate, CO₂ relative gas production rate, winding short circuit impedance initial value difference, winding insulation dielectric loss, winding capacitance initial value difference, C₂H₂ content, partial discharge quantity, gas content in oil, CH₄ content, neutral point oil flow electrostatic current, furfural content, and cardboard polymerization degree.

17. The fault locating system based on the multi-layer evaluation model as claimed in claim 8, wherein the fault determining module comprises:
an original basic probability distribution and uncertainty module for respectively adopting results of the weight coefficient calculating module and the DBN classifying module as a first independent evidence e1 and a second independent evidence e2 and respectively determining original basic probability distributions and uncertainty thereof according to a fuzzy evaluation model;
an evidence fusing module for fusing evidence to determine a confidence Bₑₗ and a likelihood pₗ of each of the fault type, wherein the confidence Bₑₗ indicates a probability of being determined as the fault type, and the likelihood pₗ indicates a probability of possibly being the fault type, that is, a total of the confidence and the uncertainty; and
a result determining module for comparing the confidence of each of the fault type calculated and choosing the highest fault type as the final determination result of the evidence inference decision.

18. The fault locating system based on the multi-layer evaluation model as claimed in claim 9, wherein the fault determining module comprises:
an original basic probability distribution and uncertainty module for respectively adopting results of the weight coefficient calculating module and the DBN classifying module as a first independent evidence e1 and a second independent evidence e2 and respectively determining original basic probability distributions and uncertainty thereof according to a fuzzy evaluation model;
an evidence fusing module for fusing evidence to determine a confidence Bₑₗ and a likelihood pₗ of each of the fault type, wherein the confidence Bₑₗ indicates a probability of being determined as the fault type, and the likelihood pₗ indicates a probability of possibly being the fault type, that is, a total of the confidence and the uncertainty; and
a result determining module for comparing the confidence of each of the fault type calculated and choosing the highest fault type as the final determination result of the evidence inference decision.
